(19) United States
(12) Patent Application Publication
(10) Pub. No.: US 2016/0268306 A1
(43) Pub. Date: Sep. 15, 2016

(54) A DISPLAY PANEL AND A METHOD FOR PRODUCING THE SAME

(71) Applicants: BOE TECHNOLOGY GROUP CO., LTD., Beijing (CN); CHENGDU BOE OPTOELECTRONICS TECHNOLOGY CO., LTD., Chengdu, Sichuan (CN)

(72) Inventors: Kun LI, Beijing (CN); Zhiqin ZHANG, Beijing (CN); Youngyik KO, Beijing (CN); Feng BAI, Beijing (CN)

(73) Assignees: BOE TECHNOLOGY GROUP CO., LTD., Beijing (CN); CHENGDU BOE OPTOELECTRONICS TECHNOLOGY CO., LTD., Chengdu, Sichuan (CN)

(21) Appl. No.: 14/408,872

(22) PCT Filed: Jun. 19, 2014
(86) PCT No.: PCT/CN2014/080300

§ 371 Date: Dec. 17, 2014

(30) Foreign Application Priority Data
Dec. 26, 2013 (CN) 201310737087.6

(51) Int. Cl. H01L 27/12; G02F 1/1339; G02F 1/1345

(52) U.S. Cl. CPC H01L 27/124; H01L 27/1262; G02F 1/1345; G02F 1/1339

(57) ABSTRACT

The present disclosure provides a display panel and a method for producing the same. An area where two sides of a first corner of a display area are located is set as a non-wiring area, an area where two sides of a second corner of the display area in an diagonal direction of the first corner are located is set as a wiring area, and peripheral wirings and peripheral arrangements of the display panel are provided in a part of the wiring area, at least one of the two sides of the second corner is located in the part of the wiring area, so that display screens with different size can be produced in a case of using only one set of mask plate, capable of saving the cost of developing and producing display panel products and shortening the development and design cycle thereof.

### CROSS-REFERENCE TO RELATED APPLICATION

The present application is the U.S. national phase of PCT Application No. PCT/CN2014/080300 filed on Jun. 19, 2014, which claims priority to the Chinese application No. 201310737087.6 filed on Dec. 26, 2013, the entire contents of which are incorporated herein by reference

### TECHNICAL FIELD

The present disclosure relates to the field of display technology, in particular to a display panel used in the process of trial-producing the display panel, a method for producing the display panel, and a display comprising the display panel.

### BACKGROUND

Currently, when manufacturers decide to produce display screen products with a certain model, they mostly use development and design procedures as shown in FIG. 1, comprising:

Step 11: determining the model of a product to be developed;

Step 12: designing a mask plate according to model appearances (comprising display size, resolution, screen size, etc.), display performance (comprising transmittance, angle of view, luminance, display mode, etc.), module specification (such as backlight requirement, driver IC), and designing the distribution of a display area on the display panel, the pixel structure, the arrangement of peripheral circuit wirings and driver IC side connection terminal being interconnected, plan and layout of test/repairing/anti-static structure, etc;

Step 13: sending the designed data to the manufacturer of the mask plate;

Step 14: producing, by the manufacturer of the mask plate, corresponding mask plate according to data and the requirements for compensation;

Step 15: sending the produced mask plate back to the manufacturer of the display panel for photoetching on a display substrate to produce corresponding circuit structure and thereby form TFT array substrate.

This existing design and, development procedure can be put into use after designing of product, sending of data, manufacturing of mask plate, and delivery of the mask plate, wherein the designing and manufacturing of the mask plate are the most time-consuming, which is unfavorable for rapid production to occupy the market. Moreover, since the circuit design of the TFT array substrate in the display panel product has a certain complexity, design errors easily exist, and most of the design errors is found by checking after products have been produced. At this time, it is required to re-design or modify the mask plate so as to waste a lot of time. Furthermore, since the cost for producing the mask plate is quite high and takes a bigger share in the development and production of the display panel, to modify and re-design the mask plate will result in an increase of production cost, which is unfavorable for reduction thereof and makes the product lose price advantage in market competition.

In developing some low-end products, of which displaying performance is not required high (even only required to be capable of displaying) and the yield is demanded quite low (usually thousands of pieces are required), the above unfavorable factors become more outstanding.

### SUMMARY

The present disclosure provides a display panel and a method for producing the same so as to shorten the cycle of developing and designing display panel products and reduce development and production cost thereof.

The present disclosure provides the following solutions:

A display panel comprising at least one display area, wherein the display panel comprises: a non-wiring area where two sides of a first corner of the display area are located; and a wiring area where two sides of a second corner of the display area in an diagonal direction of the first corner are located, wherein peripheral wirings and peripheral arrangements of the display panel are provided in a part of the wiring area, at least one of the two sides of the second corner is located in the part of the wiring area.

Preferably, the peripheral arrangements comprise: a test area, an anti-static structure, a control chip, a chip connecting terminal area, and a common electrode channel area.

Preferably, the peripheral wirings comprise: a scan line, a data line, and a common electrode line.

Preferably, the peripheral wirings comprise a connecting line among peripheral arrangements and a connecting line between the peripheral arrangements and the display area.

Preferably, the wiring area further comprises a center wiring area which is far away from the two sides of the first corner and near the second corner.

Preferably, the peripheral arrangements are further provided in the center wiring area.

Preferably, one part of the peripheral wirings are arranged in the center wiring area, and the other part of the peripheral wirings are dispersedly arranged in the part of the wiring area, at least one side of the second corner is located in the part of the wiring area.

Preferably, adjacent peripheral wirings in the other part of the peripheral wirings are arranged at a preset interval, such that when an area where peripheral wirings near the two sides of the first corner are located is cut away, peripheral wirings adjacent to the cutaway peripheral wirings remain.

Preferably, the peripheral wirings are designed in a Z shape or a rectangular-ambulatory-plane shape.

The present disclosure further provides a method for producing the above-mentioned display panel, comprising a step of providing peripheral wirings led out of a display area and peripheral arrangements of the display panel in a wiring area where at least one of two sides of a second corner is located.

Preferably, the method comprises:

determining a region to be cut away in an original display panel based on the desired size of the display panel; and cutting the region away.

Preferably, the region to be cut away is a region far away from the second corner comprising the entirety of two sides of a first corner and simultaneously comprising a part of the two sides of the second corner, or a region far away from the second corner comprising the entirety of one side of the first corner and simultaneously comprising a part of one side of the second corner.

Preferably, a display panel reserved area is reserved during cutting, the display panel reserved area configured to place a frame sealant during arranging substrates oppositely to form a cell, or to a cutting deviation reserved area.

The present disclosure further provides a display comprising the above-mentioned display panel.

As can be seen from the above description, according to the display panel and the method for producing the same as the present disclosure provided, in the display panel, an area where two sides of a first corner of the display area are located is set as a non-wiring area, an area where two sides of a second corner of the display area in an diagonal direction of the first corner are located is set as a wiring area, and peripheral wirings and peripheral arrangements of the display panel are provided in a part of the wiring area, at least one of the two sides of the second corner is located in the part of the wiring area, so that display screens with different size can be produced in a case of using only one set of mask plate, capable of saving the cost of developing and producing display panel products and shortening the development and design cycle thereof.

### BRIEF DESCRIPTION OF THE DRAWINGS

FIG. 1 is a schematic view showing the procedures for development and design of a display panel in the prior art;

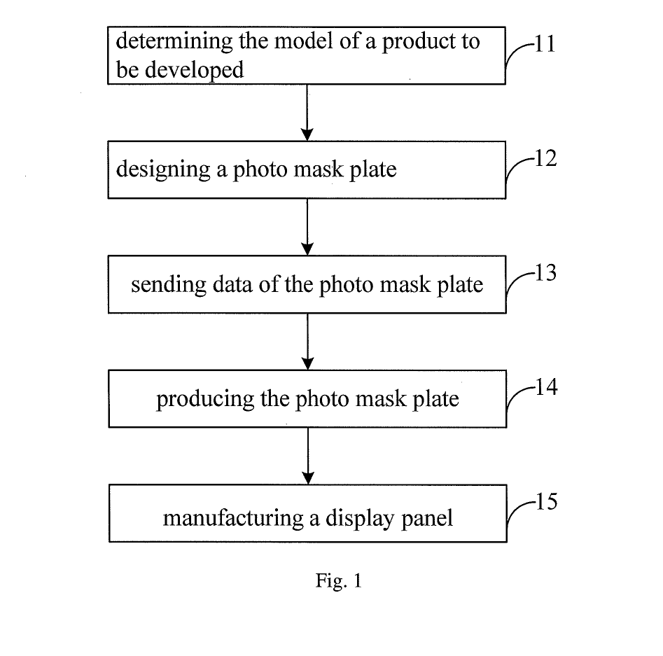

FIG. 2 is a schematic view one showing the structure of a display panel in the present disclosure;

FIG. 3 is a schematic view two showing the structure of a display panel in the present disclosure;

FIG. 4 is a schematic view three showing the structure of a display panel in the present disclosure;

FIG. 5 is a schematic view showing the procedure of a method for producing the display panel in the present disclosure;

FIG. 6 is a schematic view one showing the detailed cutting according to the method for producing the display panel in the present disclosure;

FIG. 7 is a schematic view two showing the detailed cutting according to the method for producing the display panel in the present disclosure;

FIG. 8 is a schematic view three showing the detailed cutting according to the method for producing the display panel in the present disclosure; and

FIG. 9 is a schematic view four showing the detailed cutting according to the method for producing the display panel in the present disclosure.

### DETAILED DESCRIPTION

To make the objects, the technical solutions and the advantages of the present disclosure more apparent, the technical solution of the present disclosure will be described below clearly and fully in conjunction with the drawings therein. Obviously, the embodiment described is a part of embodiments other than all the embodiments of the present disclosure. All embodiments obtained by an ordinary person skilled in the art based on the embodiment described in the present disclosure fall into the protection scope of the present disclosure.

Unless otherwise specified, the technical terms or scientific terms used herein shall be understood in a usual sense by a person having an ordinary skill in the art. “First”, “second”, and the like used in the specification and claims of the present disclosure do not indicate any order, number or importance, but merely distinguish different constituent parts. Likewise, “a”, “one” or the like does not indicate limitation to numbers, but indicates existence of at least one. “Connection”, “interconnection” or the like is not limited to physical connection or mechanical connection, but may include electrical connection, whether directly or indirectly. “Up”, “down”, “left”, “right”, etc are merely for indicating relatively positional relations. When the absolute position of an object to be described changes, the relatively positional relation changes accordingly.

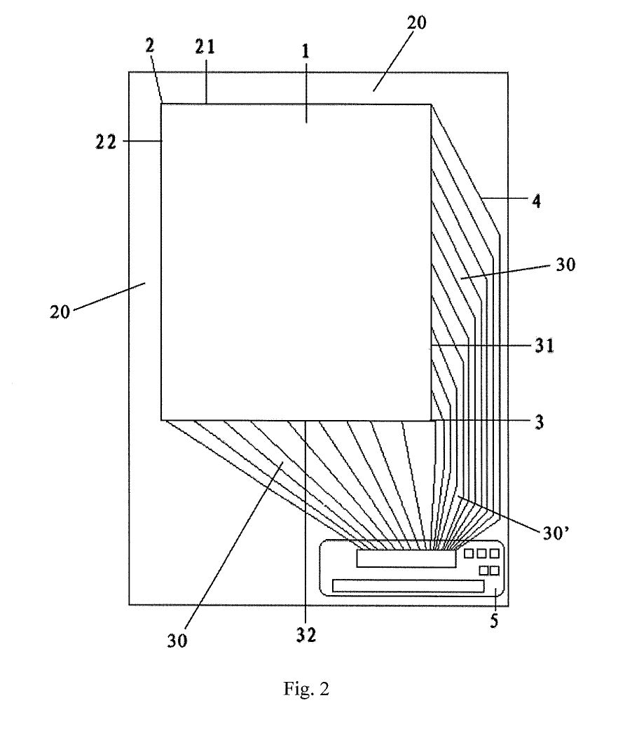

The present disclosure provides a display panel. As shown in FIG. 2, the display panel specifically comprises at least one display area 1;

In the display panel, an area where two sides 21, 22 of a first corner 2 of the display area 1 are located is a non-wiring area 20;

In the display panel, an area where two sides 31, 32 of a second corner 3 of the display area 1 in a diagonal direction of the first corner 2 is a wiring area 30;

Peripheral wirings 4 and peripheral arrangements of the display panel are provided in a part of the wiring area 30 at least one of the two sides 31, 32 of the second corner 3 is located in the part of the wiring area 30.

According to the display panel as provided in the present disclosure, the peripheral wirings and the peripheral arrangements are provided in the wiring area 30 of the display panel where the two sides corresponding to the second corner 3 of the display area 1 are located, and a display panel area where the two sides corresponding to the first corner 2 of the display area in a diagonal direction of the second corner 3 are located is set as the non-wiring area 20. The wiring area 30 further comprises a center wiring area 30′ which is far away from the two sides of the first corner 2 and near the second corner 3.

When it is required to produce a display panel with other sizes, it is possible to cut away an unnecessary display panel part comprising the two sides corresponding to the first corner 2, the cutaway display panel part comprising a part of the wiring area 30 near the two sides of the first corner 2, and the display panel after the cuffing at least remains a center wiring area 30′ in the wiring area 30 so that display screens with different size can be produced in a case of using only one set of mask plate, capable of saving the cost of developing and producing display panel products and shortening the development and design cycle thereof.

The peripheral wirings 4 involved in the present disclosure can specifically comprise a scan line, a data line, and a common electrode line. The process and method for producing the peripheral wirings 4 involved in the present disclosure can be identical to the existing mature technology.

In the detailed embodiment, in order to avoid destroying the peripheral wirings 4 to be reserved during cutting, a part of the peripheral wirings 4 involved in the present disclosure is arranged in the center wiring area 30′, and the other part is dispersedly arranged in a part of the wiring area, at least one side of the second corner 3 is located in the part of the wiring area 30. Moreover, adjacent peripheral wirings in the other part of the peripheral wirings are arranged at a preset interval, such that when an area where peripheral wirings near the two sides of the first corner 2 are located is cut away, the peripheral wirings adjacent to the cutaway peripheral wirings remain.

The peripheral arrangements involved in the present disclosure can specifically comprises a test area, an anti-static structure, a control chip IC, a chip connecting terminal area, a common electrode channel area, etc. That is, as shown in FIG. 2 of the present disclosure, the peripheral arrangements of the display panel can be arranged in the center wiring area 30′ of the wiring area 30.

The specific structure of the display panel as provided in the present disclosure will be described detailed hereinafter in conjunction with the drawings.

In the array layout of the design scheme of the display panel as shown in FIG. 2, the peripheral wirings (i.e., the scan line, the data line, the common electrode line, etc. led out of the display area 1) and the peripheral arrangements (i.e., the test area, the anti-static structure, the control chip, the chip connecting terminal area, an upper and lower common electrode channel area, etc) of the display panel are provided in an area below the side 32 corresponding to the second corner 3 of the display area 1 and in an area on the right of the side 31, i.e., in the “wiring area” involved in the present disclosure, and the control chip, the chip connecting terminal area, a test/anti-static structure area, etc. are all near the second corner 3, i.e., positioned in the center wiring area 30′ of the wiring area 30. It has to be indicated that, in the embodiment as shown in FIG. 2, the wiring area 30 involved in the present disclosure is two sides of the second corner 3 of the display area 1, but in the practical application, it is also possible to arrange the wiring area 30 involved in the present disclosure in an area where two sides corresponding to other corners of the display area 1 are located.

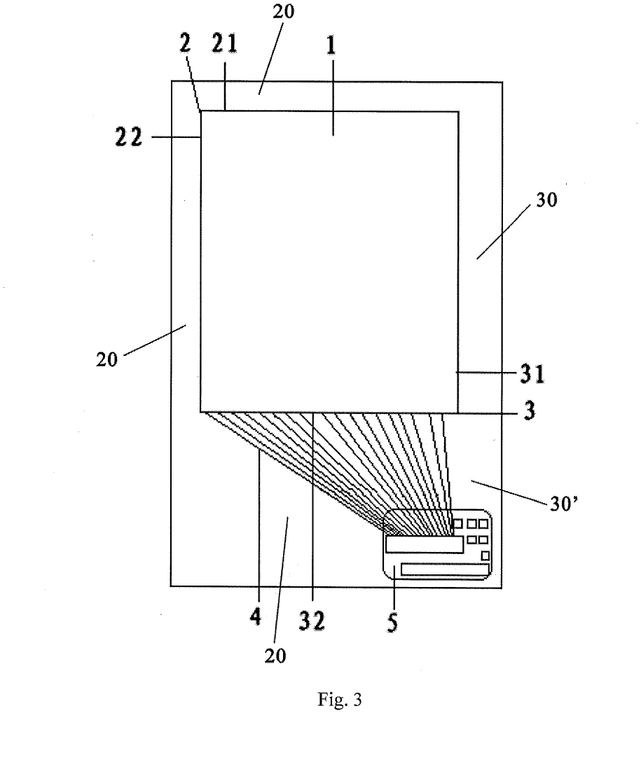

In another embodiment, if a wiring scheme of winding driving technology (GIA: Gate fanout In Active area) in the panel (i.e., the scan line is arranged in a pixel area and parallel to the data line) or a scheme of the scan line (data line) arranging on a substrate (i.e., a non-TFT array substrate) is used for an array substrate included in the display panel, all peripheral wirings and the peripheral arrangements in the display panel are provided in a single side area of the display area 1, and all the control chip, the control chip connecting terminal area, the test/anti-static structure area, etc. are near one end of the side area. The array layout of the design scheme of the display panel is, to be specific, as shown in FIG. 3. Likewise, the peripheral wirings and the peripheral arrangements in FIG. 3 are provided below the shown display area 1 and near a right end, and it is possible to be on the upper, left, or right side of the display area 1 and combine with any one of adjacent ends.

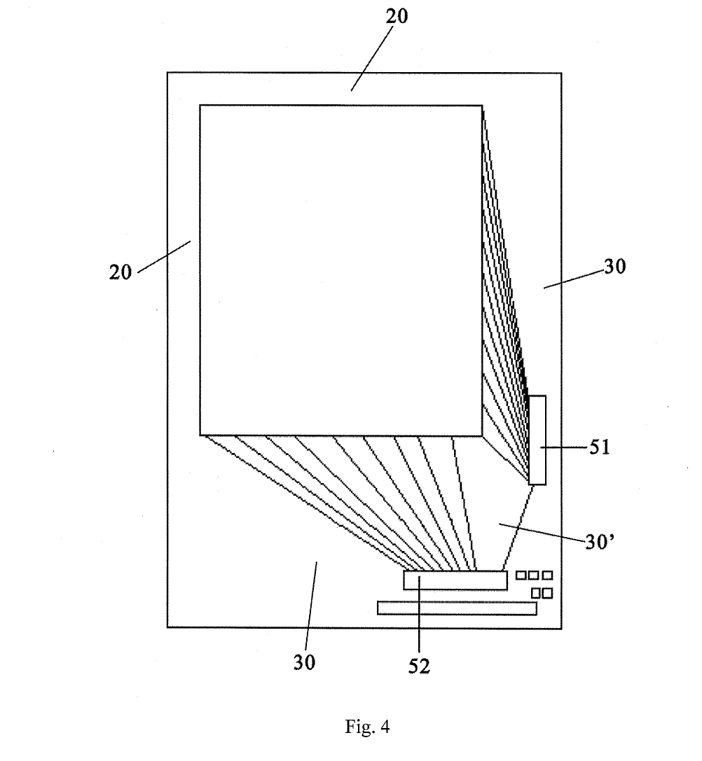

In another embodiment, a control chip 51 of the scan line and a control chip 52 of the data line can be arranged separately in the present disclosure, as shown in FIG. 4. In the meanwhile, the scan line or the data line in the present disclosure may further have a plurality of partition control chips to control respectively. Simply ensure the control chip 51 of the scan line, the control chip 52 of the data line or the partition control chips are arranged in the center wiring area 30′ not to be cut away.

The peripheral wirings 4 involved in the present disclosure is designed asymmetrically, which is different from the prior art, it is possible to use special wiring design means in the disclosure, for example, to design the wirings in a Z shape/a rectangular-ambulatory-plane shape, so as to reduce unevenness of resistance resulted from asymmetrical design. However, in the displaying of a twisted nematic liquid crystal-typed LCD, the upper and lower common electrode channel area positioned above the display area in the prior art can be arranged in the airable area, or common electrodes are interconnected by evenly distributed arrangement among scan lines and/or data lines.

The display panel area except an active display area can be used to place a frame sealant during arranging substrates oppositely to form a cell, or can be used as a cutting deviation reserved area or the like.

The present disclosure provides a method for producing a display panel, comprising a step of providing peripheral wirings led out of a display area and peripheral arrangement of the display panel in a wiring area where at least one of two sides of a second corner is located.

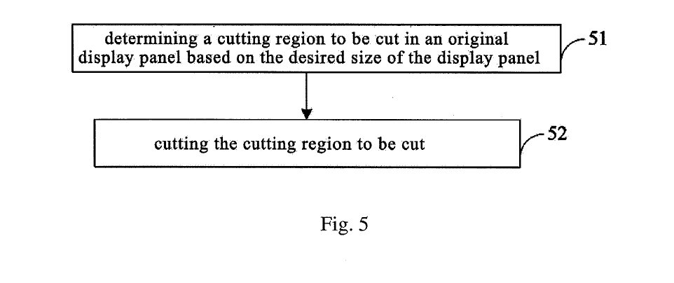

As shown in FIG. 5, the method can further comprises:

Step 51: determining a region 40 to be cut away in an original display panel based on the desired size of the display panel; and

Step 52: cutting the region 40 to be cut away.

The method for producing the display panel as provided in the present disclosure will be described detailed hereinafter in conjunction with embodiment.

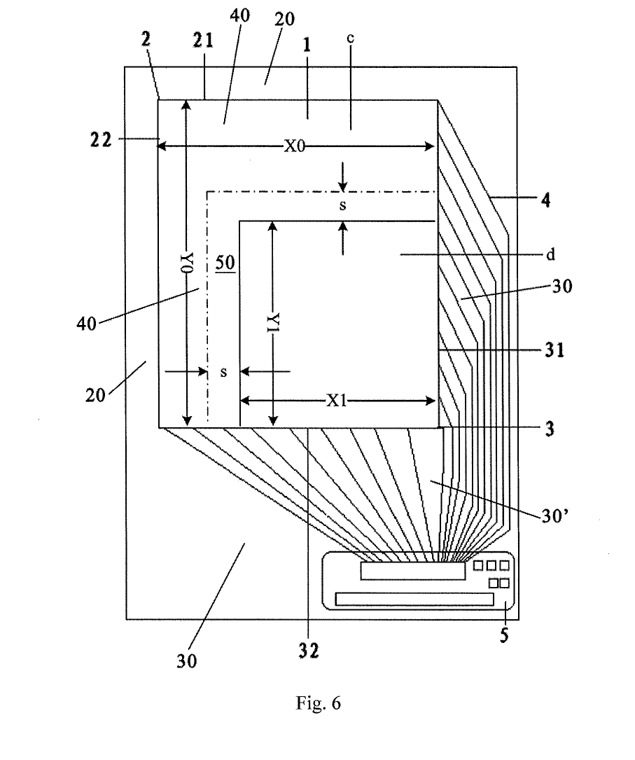

If a display panel product d has a size less than a certain developed display panel product c as shown in FIG. 2, it is possible to cut off the unnecessary display area (the region 40 to be cut away) of the TFT array substrate of the developed product c according to the size of the product d, wherein the region 40 to be cut away is a region comprising the entirety of two sides 21, 22 of a first corner 2 far away from the second corner 3 and simultaneously comprising a part of the two sides 31, 32 of the second corner 3. For example, when the product d has a size of x1 in length and y1 in width, and the developed product c has a size of x0 in length and y0 in width, and when x1<x0, y1<y0, the cutting schematic view is as shown in FIG. 6.

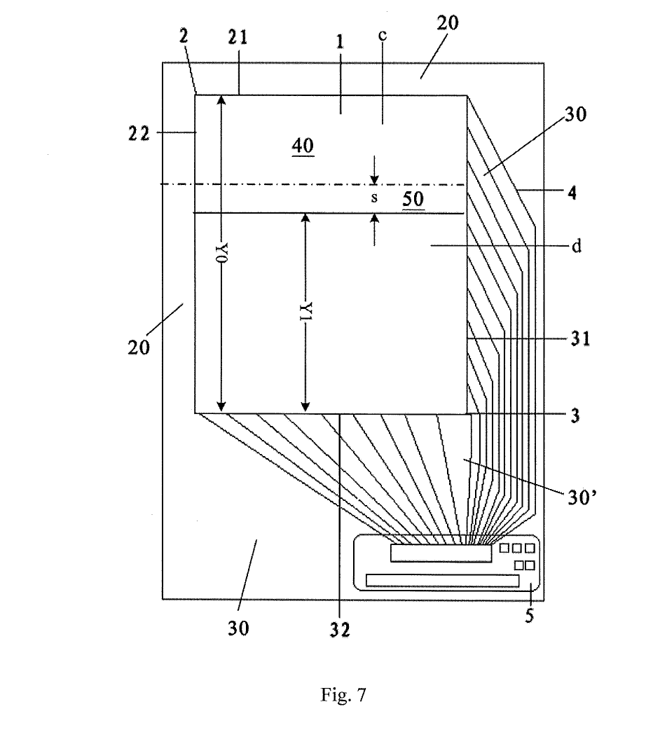

If x1=x0, the cutting schematic view is as shown in FIG. 7. When y1=y0, the schematic view is similar to FIG. 7, which is not stated here again, but their difference lies in that the region 40 to be cut away is a region comprising the entirety of one side 21 of the first corner 2 far away from the second corner 3 and simultaneously comprising a part of one side 31 of the second corner 3.

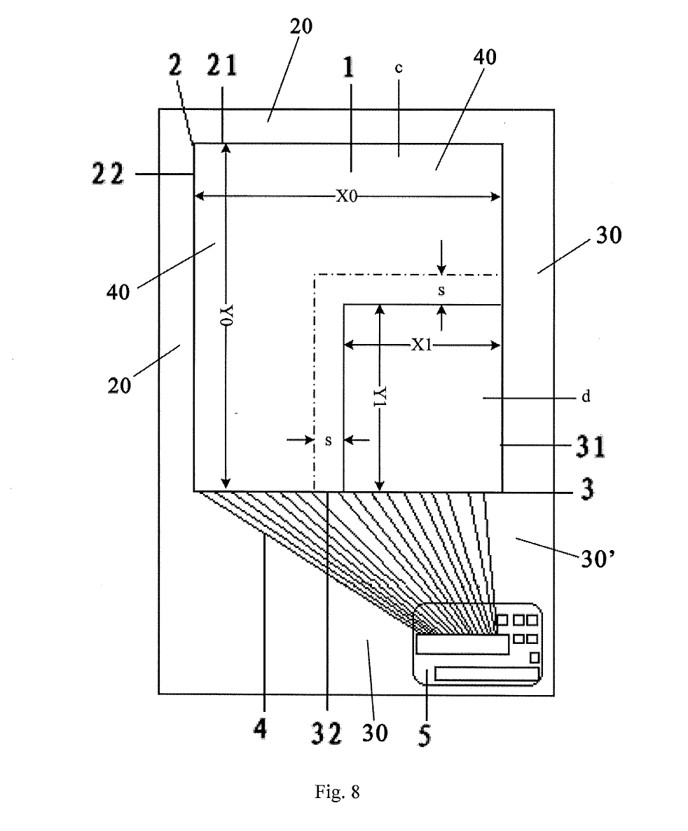

If the structure of the developed product c is as shown in FIG. 3, the schematic view of the region 40 to be cut away can be as shown in FIG. 8.

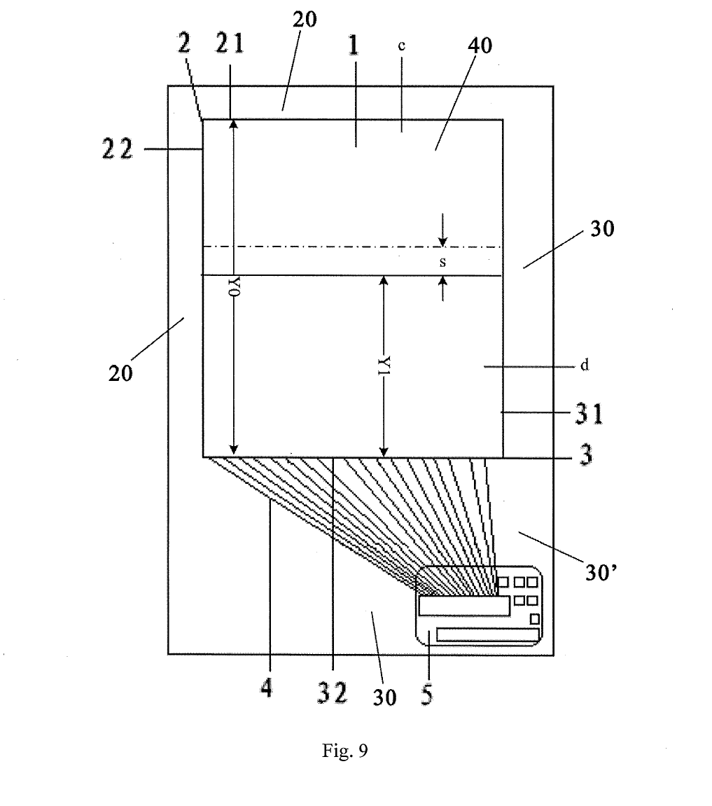

Similarly, if x1=x0, the cutting schematic view can be as shown in FIG. 9. When y1=y0, the schematic view is similar to FIG. 9, which is not stated here again.

In the embodiment as shown in FIGS. 6 and 8, values of x1 and y1 are not fixed, provided y1≦y0 while x1≦x0.

It has to be indicated that in the embodiment as shown in FIGS. 6-9, the width indicated by parameter s is a width of a display panel reserved area 50. The display panel reserved area 50 is reserved during cutting, and is not taken as a pixel area of displaying, but can be used to place a frame sealant during arranging substrates oppositely to form a cell or can be used as a cutting deviation reserved area, and a reserved width s is adjustable according to process conditions or requirements of users. In the cutting manners as shown in FIGS. 6 and 8, widths s in the horizontal and vertical directions may be different from each other.

Using the display panel and the method for producing the same as provided in the present disclosure, crucial peripheral arrangement such as the control chip, the control chip connecting terminal area, the upper and lower common electrode channel area and the test/anti-static structure is avoided during cutting so that the display area to be reserved after the cutting may display normally and perform operations such as testing. Moreover, a part of peripheral wirings 4 is arranged in the center wiring area 30′, the other part is dispersedly arranged in a part of the wiring area 30, at least one side of the second corner is located in the part of the wiring area 30, and the distance between adjacent peripheral wirings 4 can ensure no interaction during cutting so that the wirings required for displaying no longer need to be repaired by means of line repairing such as welding after the cutting.

In the present disclosure, in order to ensure that crucial peripheral arrangement such as the control chip, the control chip connecting terminal area, the upper and lower common electrode channel area and the test/anti-static structure is avoided during cutting, the manner of being far away from the first corner 2 is adopted accordingly for alignment design when conducting procedures such as testing, binding of module control chip (i.e., an end/a corner far away from the first corner 2 is used as basis reference for alignment marks and alignment manners of binding of the control chip, testing, etc).

Furthermore, in the present disclosure, because the pixel area reserved not for displaying can also display normally, it can be sheltered with the design of black matrix on a color film substrate or by means of a frame sealant, added coating, module frame, etc. so as not to affect the display effect of a normal area.

In the present disclosure, parameters such as the number of pixels per inch having in the developed product c and the product d may be the same or different. For reducing difference in visual displaying effect, when selecting the original product c to be cut according to the product d, try to select the original product c having optical parameters such as PPI and contrast ratio identical or similar to the product d. Since the requirement for display performance is not high for new low-end products, difference in parameters such as PPI, luminance and contrast ratio can be narrowed through process parameters, for example, using different liquid crystal materials and polarizers, or adjusting module backlight, control chip, gray scale, etc. If product demanders have no particular requirements for display effect, but only requests the display screen to display normally, these process parameters are not necessarily adjusted. That is, the display panel and the method for producing the display panel as provided in the present disclosure are especially suitable for use in the manufacture of low-end display screen which has low requirement for display qualities, such as resolution, and production yield.

Although the panel designing scheme as provided in the present disclosure reduces availability of glass, the cost increased due to availability of glass and utilization of materials is far lower than that of developing a new set of TFT array mask plate in a case of low demand for products, and meanwhile saves the time for designing, producing and transporting the product mask plates, and decreases the production cycle effectively.

The panel designing scheme as provided in the present disclosure may omit the development and production procedures to select an existing product only according to the requirements for a product to be developed and confirm parameters for cutting, gluing, etc. After conducting the box forming process treatment of gluing and jointing a produced TFT substrate and an upper substrate, it is cut according to cutting parameters, thereby economizing the procedures for producing the display panel.

The display panel and the method for producing the same as provided in the present disclosure are suitable not only for LCD display panel, but also for display panels such as OLED LTPS and electronic paper. All panels using the TFT structure for achievement of displaying can adopt the technical solution of the present disclosure so that display screens with different size can be produced in a case of using one set of mask plate for use in array substrate, shortening the cycle of development and design of the products and having more effective economic benefit.

The above are merely the embodiments of the present disclosure. It should be pointed out that, for one of ordinary skills in the art, many improvements and modifications can be made without departing from the principle of the present disclosure, and all these improvements and modifications fall into the protection scope of the present disclosure.

What is claimed is:

1. A display panel comprising at least one display area, wherein the display panel comprises:
a non-wiring area where two sides of a first corner of the display area are located; and
a wiring area where two sides of a second corner of the display area in an diagonal direction of the first corner are located;
wherein peripheral wirings and peripheral arrangements of the display panel are provided in a part of the wiring area, at least one of the two sides of the second corner is located in the part of the wiring area.

2. The display panel according to claim 1, wherein the peripheral arrangements comprise: a test area, an anti-static structure, a control chip, a chip connecting terminal area, and a common electrode channel area.

3. The display panel according to claim 1, wherein the peripheral wirings comprise: a scan line, a data line, and a common electrode line.

4. The display panel according to claim 1, wherein the peripheral wirings comprise a connecting line among peripheral arrangements and a connecting line between the peripheral arrangements and the display area.

5. The display panel according to claim 1, wherein the wiring area further comprises a center wiring area which is far away from the two sides of the first corner and near the second corner.

6. The display panel according to claim 5, wherein the peripheral arrangements are further provided in the center wiring area.

7. The display panel according to claim 5, wherein one part of the peripheral wirings are arranged in the center wiring area, and the other part of the peripheral wirings are dispersedly arranged in the part of the wiring area, at least one side of the second corner is located in the part of the wiring area.

8. The display panel according to claim 7, wherein adjacent peripheral wirings in the other part of the peripheral wirings are arranged at a preset interval such that when an area where peripheral wirings near the two sides of the first corner are located is cut away, peripheral wirings adjacent to the cutaway peripheral wirings remain.

9. The display panel according to claim 1, wherein the peripheral wirings are designed in a Z shape or a rectangular-ambulatory-plane shape.

10. A method for producing a display panel according to claim 1, comprising a step of providing peripheral wirings led out of a display area and peripheral arrangement of the display panel in a part of the wiring area, at least one of two sides of a second corner is located in the part of the wiring area.

11. The method according to claim 10, wherein the method comprises:
determining a region to be cut away in an original display panel based on the desired size of the display panel; and
cutting the region away.

12. The method according to claim 11, wherein the region to be cut away is a region far away from the second corner comprising the entirety of two sides of a first corner and simultaneously comprising a part of the two sides of the second corner, or a region far away from the second corner comprising the entirety of one side of the first corner and simultaneously comprising a part of one side of the second corner.

13. The method according to claim 11, wherein a display panel reserved area is reserved during cutting, the display panel reserved area being used to place a frame sealant during arranging substrates oppositely to form a cell, or used as a cutting deviation reserved area.

14. A display comprising a display panel according to claim 1.

15. The display panel according to claim 2, wherein the peripheral wirings comprise: a scan line, a data line, and a common electrode line.

16. The display panel according to claim 2, wherein the peripheral wirings comprise a connecting line among peripheral arrangements and a connecting line between the peripheral arrangements and the display area.
